(19) United States
(12) Patent Application Publication
(10) Pub. No.: US 2011/0071036 A1
(43) Pub. Date: Mar. 24, 2011

(54) ISOELECTRIC FOCUSING BIOCHIP

(75) Inventors: Roel Penterman, Eindhoven (NL); Christopher James Backhouse, Edmonton (CN)

(73) Assignee: KONINKLIJKE PHILIPS ELECTRONICS N.V., EINDHOVEN (NL)

(21) Appl. No.: 12/993,108

(22) PCT Filed: May 18, 2009
(86) PCT No.: PCT/IB2009/052054

§ 371 Date: Nov. 17, 2010

(30) Foreign Application Priority Data
May 27, 2008 (EP) 08104113.9

(51) Int. Cl. C40B 30/00; H01L 21/00; G01N 35/10; G01N 27/447

(52) U.S. Cl. 506/7; 438/49; 73/64.56; 204/610

(57) ABSTRACT

The present invention relates to an isoelectric focusing biochip, in particular for fractionating, detecting and/or collecting analytes, such as proteins, metabolites, glycoproteins and/or peptides, a method for fractionating, detecting and/or collecting analytes, with such a biochip and a manufacturing method for such a biochip.

### FIELD OF THE INVENTION

The present invention is directed to the field of devices for the separation of analytes, such as proteins, metabolites, glycoproteins and/or peptides, on the basis of isoelectric focusing.

### BACKGROUND OF THE INVENTION

In proteomics there is no amplification step for proteins like the PCR method for amplifying nucleic acids in DNA assays. Furthermore, there is a high dynamic range and diversity of expressed proteins particularly in eukaryotic tissues. Therefore, the sample is preferably prefractionated to reduce the complexity of the sample mixtrure, to enrich the sample for certain proteins, such as low abundant proteins or alkaline proteins, and to get some information on the topology of the proteins. A very useful way to prefractionate the sample is electrophoretic prefractionation according to the iso-electric point (pI) in the liquid phase.

Multi-compartment electrolyzers have been developed for this by Righetti and co-workers and are commercialized by Proteome Systems under the name IsoelectrIQ. These chips consist of multiple chambers separated by isoelectric membranes. Each membrane comprises an Immobiline gel which locally buffers the pH in the membrane. From the anode towards the cathode the pI of the membranes is increased in incremental steps, creating multiple pI intervals. In one of the chambers the protein sample is introduced and when a voltage is applied between anode and cathode and each protein moves to the pI chamber which matches with its pI. After the fractionation the liquid in each chamber is collected for further analysis.

The major drawbacks of current electrolyzers like the instrument described above is that they are sophisticated, e.g. contain many parts that prior to use need to be assembled by skilled personnel and still require a lot of handling steps. Furthermore, the sample is usually diluted during or after the separation process, which effectively lowers the detection limit for low-abundant proteins. The volume of the individual chambers in Multi-compartment electrolyzers IsoelectrIQ is with approximately 5 ml relatively large.

The object of the present invention is to overcome the mentioned above problems and to provide an automatable device capable to fractionate very small sample volumes.

### SUMMARY OF THE INVENTION

The present invention relates to a isoelectric focusing biochip, in particular for fractionating, detecting and/or collecting analytes, such as proteins, metabolites, glycoproteins and/or peptides, comprising
a microfluidic sample channel,
a first gel pad having a first pH value (pH1),
a second gel pad having a second pH value (pH2) different to the first pH value (pH1), and
an anode-cathode pair,

whereas the first and the second gel pad form at least two opposite wall parts of the sample channel, and

whereas at least one part of the first gel pad, at least one part of the second gel pad and the part of the sample channel, whose opposite wall parts are formed by the first and the second gel pad, are arranged between the anode and the cathode of the anode-cathode pair.

Within the scope of the present invention under the term “microfluidic” is understood that the channels, chambers and reservoirs of the biochip have a volume of the order of micro liters, for example of ≧0.01 μl to ≦50 μl, in particular of ≧0.1 μl to ≦10 μl.

In an isoelectric focusing biochip according to the present invention, most of the fractionation, detection and separation steps can advantageously be automated. Thereby, advantageously, the reproducibility of the results is improved and the fractionation speed is increased.

Furthermore, the biochip according to the invention is advantageously capable to fractionate very small sample volumes, for example in the order of some micro liters. That is to say, the biochip according to the invention can fractionate sample volumes, which are about at least the factor 1000 lower than the sample volumes needed for separation devices of the state-of-the-art. Therefore, the sample does not need to be diluted prior to the separation. Theoretically, this could lead to 1000 times more concentrated protein samples after fractionation.

Since in the biochip according to the invention only small sample volumes are needed and dilution of the sample can be omitted, the biochip according to the invention advantageously has an increased detection limit, which is very important, in particular for the detection of low-abundant proteins.

Within the scope of a preferred embodiment of the invention, the biochip further comprises at least one microfluidic fractionation channel and for each fractionation channel an additional gel pad having a pH value different to the pH values of the other gel pads. The additional gel pad and the first gel pad or the second gel pad or a further additional gel pad thereby preferably form at least two opposite wall parts of the fractionation channel. To ensure isoelectric movement of the analytes of the sample into the fractionation channel and/or the additional gel pad, the part of the fractionation channel, whose opposite wall parts are formed by the additional gel pad and the first gel pad or the second gel pad or a further additional gel pad, and at least one part of the additional gel pad are arranged between the anode and the cathode of the anode-cathode pair.

Within the scope of a further preferred embodiment of the invention the biochip comprises at least one additional anode-cathode pair. Thereby the biochip comprises for each additional anode-cathode pair at least two further gel pads having pH values different to each other and to the pH values of the other gel pads. Analog to the first and the second gel pad of the first anode-cathode pair, also the two gel pads of the additional anode-cathode pair form at least two opposite wall parts of the sample channel. And to ensure the isoelectric movement of the analytes of the sample into the further gel pads and optionally into further fractionation channels, also the part of the sample channel, whose opposite wall parts are formed by the two gel pads of the additional anode-cathode pair, and at least one part of each of the two gel pads of the additional anode-cathode pair are arranged between the anode and the cathode of the additional anode-cathode pair.

The use of at least two cathode-anode pairs has the advantage that the sample can be pre-fractionated in a first fractionation step, for example to remove high abundant proteins, for example albumin and immunoglobulin which comprise over 90% of the proteome by weight. The removal of high abundant proteins in the first step advantageously prevents protein precipitation in the ultimate (second) fractionation. In a second fractionation step the analytes are then advantageously further up concentrated.

Advantageously, the anode and cathode of the first or an additional anode-cathode pair are electrically connected to the two external gel pads of one anode-cathode pair. That is to say, the anode is electrically connected to the gel pad farthest to one side of the sample channel and the cathode is electrically connected to the gel pad farthest to the opposite side of the sample channel.

For introducing the sample and optionally removing the fractionated sample after isoelectric focusing, the sample channel is preferably provided with a sample inlet and/or a sample outlet. For the same reason, each fractionation channel is preferably provided with a fractionation inlet and/or a fractionation outlet and/or each internal gel pad is preferably provided with a gel inlet and/or gel outlet, in particular a gel inlet.

Within the scope of an embodiment of the biochip according to the invention, the two external gel pads of one anode-cathode pair are provided with an anode inlet and a cathode inlet, respectively. By this means, not only an electric contact of the electrodes and the gels can simply be achieved, but also the manufacture of the biochip can advantageously be simplified.

Within the scope of another embodiment of the biochip according to the invention, the sample inlet, sample outlet, fractionation inlet, fractionation outlet, gel inlet, gel outlet, anode inlet and/or cathode inlet is provided with a flow barrier.

For opening the flow barrier and/or moving an analyte fraction, the sample channel and/or at least one fractionation channel and/or at least one gel pad, in particular the sample channel and/or at least one fractionation channel, can be connected to a pressure means. Within the scope of the present invention, the sample channel, the fractionation channel and/or the gel pad can thereby be directly or indirectly, for example via the sample inlet, a fractionation inlet and/or a gel inlet and/or via a buffer reservoir, be connected to the pressure means.

Within the scope of a further embodiment of the biochip according to the invention, the sample channel and/or at least one fractionation channel and/or at least one gel pad, in particular the sample channel and/or at least one fractionation channel, is connected or connectable via the sample outlet, a fractionation outlet and/or a gel outlet, in particular the sample outlet and/or a fractionation outlet, to an analyte detector and/or analyte collector and/or a further analyte separator. For example, the sample channel and/or at least one fractionation channel and/or at least one gel pad, in particular the sample channel and/or at least one fractionation channel, is connectable to an analyte detector and/or analyte collector and/or a further analyte separator by opening the flow barrier of the sample outlet, fractionation outlet and/or gel outlet, in particular the sample outlet and/or a fractionation outlet. Preferably the analyte detector, analyte collector and/or further analyte separator is thereby integrated in the biochip. A suitable analyte separator and detector may for example be based on a narrow range isoelectric focusing zoom gel with pH gradient provided with an immunoassay means.

Within the scope of yet another embodiment of the biochip according to the invention, the sample channel and/or at least one fractionation channel and/or at least one gel pads is connected or connectable via the sample inlet, a fractionation inlet and/or a gel inlet, in particular the sample inlet and/or a fractionation inlet, to a buffer reservoir. For example, the sample channel and/or at least one fractionation channel and/or at least one gel pad, in particular the sample channel and/or at least one fractionation channel, is connectable to a buffer reservoir by opening the flow barrier of the sample inlet, a fractionation inlet and/or a gel inlet. The buffer reservoir thereby preferably comprises at least one buffer.

By combining the above-mentioned embodiments, it is possible to transfer an analyte into the analyte detector and/or analyte collector and/or a further analyte separator by applying a pressure to the buffer in the buffer reservoir, opening both flow barriers and flushing the buffer through the sample channel, fractionation channel or gel pad into the analyte detector, analyte collector and/or analyte separator.

For example, the sample channel is connectable to a buffer reservoir by opening the flow barrier of the sample inlet and to a detection chamber by opening the flow barrier of the sample outlet and/or at least one fractionation channel is connectable to a buffer reservoir by opening the flow barrier of the fractionation inlet and to a detection chamber by opening the flow barrier of the fractionation outlet and/or at least one gel pad is connectable to a buffer reservoir by opening the flow barrier of the gel inlet and to a detection chamber by opening the flow barrier of the gel outlet.

Preferably, the sample channel and/or at least one fractionation channel is connectable to a buffer reservoir by opening the flow barrier of the sample/fractionation inlet and to a detection chamber by opening the flow barrier of the sample/fractionation outlet.

Within the scope of a yet another preferred embodiment of the biochip according to the present invention, the detection chamber is connectable by opening a further flow barrier to a detection probe reservoir.

Preferably, also the buffer reservoir and/or the detection chamber and/or the detection probe reservoir are provided with an inlet, in particular provided with a flow barrier, for example a septum, through which the detection probe can be inserted manually or automatically, to allow the detection of user defined analytes and/or the removal of fractionated analytes.

Within the scope of the present invention, the sample channel, a fractionation channel, a gel pad, a buffer reservoir, a detection chamber and/or a detection probe reservoir may comprise at least one analyte detecting compound, for example an immunoassay compound.

In particular, the biochip according to the invention may comprise at least one capture probe and/or at least one detection probe as analyte detecting compounds.

Within the scope of a preferred embodiment of the biochip according to the present invention, the detection chamber preferably comprises at least one, for example at least five, in particular a plurality of, capture probes. Preferably, the capture probe is thereby covalently bond to the wall of the detection chamber.

According to the invention, a capture probe is capable to interact with the analyte, for example via antibody-antigen, protein-protein, and protein-metabolite interaction A capture probe may be a capture antibody, a capture antigen, a capture protein, a capture metabolite or another molecule having a high affinity to an analyte, for example a single chain variable fragments (scFv).

Preferably thereby, the buffer reservoir and/or the detection chamber and/or the detection probe reservoir comprises at least one, in particular corresponding, detection probe, preferably a labeled detection probe, for example a labeled detection antibody.

Within the scope of a preferred embodiment of the biochip according to the invention, the sample channel is provided with at least one flow barrier for separating the interaction of the sample with the gel pad/s of the first anode-cathode pair and with the gel pad/s of the additional anode-cathode pairs.

For this purpose, the flow barrier can for example be arranged in the sample channel at a position situated between the part of the sample channel, whose opposite wall parts are formed by the first and the second gel pad, and the part of the sample channel, whose opposite wall parts are formed by the two gel pads of the additional anode-cathode pair.

In particular, the sample channel may comprise for each anode-cathode pair a first and a second flow barrier. These flow barrier are preferably positioned at the beginning and at the end of the part of the sample channel, whose opposite wall parts are formed by two gel pads. By this means, the sample is advantageously kept in the area between the anode and the cathode during isoelectric focusing

Generally, all known flow barriers for microfluidic channels, such as micro valves, can be used for a biochip according to the invention.

In one embodiment of the biochip according to the present invention, at least one flow barrier is a hydrophobic stop barrier.

A hydrophobic stop barrier can be achieved by coating at least one area inside a capillary, such as the sample channel or a fractionation channel, with at least one water repellant agent, such as 1H,1H,2H,2H-perfluoroalkyltrihalogenosilanes, for example 1H,1H,2H,2H-perfluorohexyltrichlorosilane, 1H,1H,2H,2H-perfluorooctyltrichlorosilane, 1H,1H,2H,2H-perfluorodecyltrichlorosilane and/or 1H,1H,2H,2H-perfluorododecyltrichlorosilane, in particular 1H,1H,2H,2H-perfluorodecyltrichlorosilane, and/or 1H,1H,2H,2H-perfluoroalkyltrialkoxysilanes, for example 1H,1H,2H,2H-perfluorohexyltrimethoxysilane, 1H,1H,2H,2H-perfluorooctyltrimethoxysilane, 1H,1H,2H,2H-perfluorodecyltrimethoxysilane, 1H,1H,2H,2H-perfluorododecyltrimethoxysilane, 1H,1H,2H,2H-perfluorohexyltriethoxysilane, 1H,1H,2H,2H-perfluorooctyltriethoxysilane, 1H,1H,2H,2H-perfluorodecyltriethoxysilane and/or 1H,1H,2H,2H-perfluorododecyltriethoxysilane, in particular 1H,1H,2H,2H-perfluorodecyltrimethoxysilane and/or 1H,1H,2H,2H-perfluorodecyltriethoxysilane, and/or Teflon (poly-perfluoroethylene) based compounds, for example Teflon AF1600, and/or a compound of the formula (III):

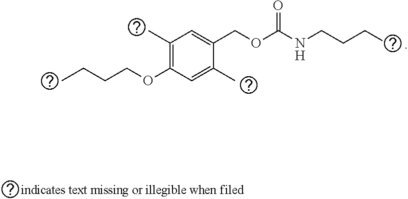

Such a coating ensures that a liquid, for example the sample, a fraction of the sample or a buffer, is stopped at the position of the coating (see FIGS. 5a to 5c and figure description). Depending on the used water repellant agent, the hydrophobic stop barrier can be actuated/opened by applying a pressure or a high voltage on the stopped liquid, by changing/increasing the temperature, by temporarily decreasing the cross section dimension of the capillary and/or by ultra violet radiation. For example a hydrophobic compound of the general formula (III) decomposes under radiation with ultra violet light to a hydrophilic compound.

Within the scope of a preferred embodiment of the invention, the gel pads are made by co-polymerization of at least acrylamide monomers:

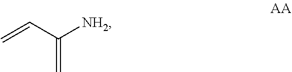

N,N′-methylenebisacrylamide monomers:

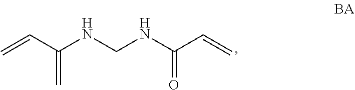

and

monomers comprising one or more pH-buffering subunits (immobiline monomers), for example acrylamide monomers comprising one or more pH-buffering subunits, such as immobiline A (buffering the gel at ≈pH 4.5) of the formula I:

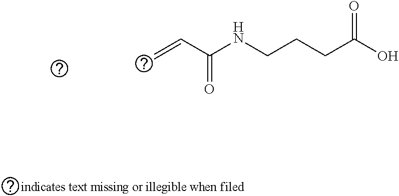

and

immobiline B (buffering the gel at ≈pH 8.5) of the formula II:

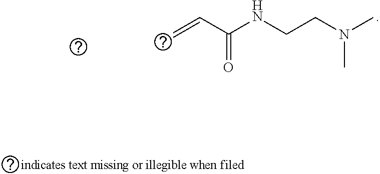

To enable the separation of analytes, within the scope of the present invention the pH values of the gel pads increase from the gel pad closest to the anode to the gel pad closest to the cathode.

For proper continuously mixing and to prevent electrodecantation, the biochip according to the invention comprises a micromixer. Examples of suitable micromixers are poly-MEMS (Micro Electro Mechanical System) or magnetic micro- or nanorods moved by (rotating) external magnetic fields.

The sample channel and/or the fractionation channels and/or the reservoirs and/or the chambers can for example have a volume of about ≧0.1 μl to about ≦50 μl, in particular of about ≧1 μl to about ≦10 μl, and/or a width of about ≧0.2 mm to about ≦5 mm, in particular of about ≧0.5 mm to about ≦1.5 mm, and/or a height of about ≧1 μm to about ≦500 μm, in particular of about ≧10 μm to about ≦200 μm, and/or a length of about ≧1 mm to about ≦100 mm, for example of about ≧1 mm to about ≦50 mm, in particular of about ≧5 mm to about ≦20 mm. The gel pads can for example have a volume of about ≧0.1 μl to about ≦50 μl, in particular of about ≧1 μl to about ≦10 μl,

and/or a width of about ≧1 mm to about ≦20 mm, in particular of about ≧5 mm to about ≦10 mm, and/or a height of about ≧1 μm to about ≦500 μm, in particular of about ≧10 μm to about ≦200 μm, and/or a length of about ≧1 mm to about ≦100 mm, for example of about ≧1 mm to about ≦50 mm, in particular of about ≧5 mm to about ≦20 mm. In particular, the length of the gel pads is thereby defined in the same direction as the length of the sample channel. The anode/s and cathode/s can for example comprise, in particular consist of, platinum, gold, copper, aluminum or doped silicon, preferably coated with a platinum layer.

To ensure that the gels in the biochip stay hydrated during storage, the biochip preferably comprises a, in particular removable, sealing and/or is placed in a sealed box, for example filled with water. This has the advantage that the biochip can be used immediately when needed and no time-consuming rehydration step is required.

Another subject of the present invention is a method for fractionating, detecting and/or collecting analytes, such as proteins, metabolites, glycoproteins and/or peptides, with a biochip according to any one of the preceding claims, comprising the steps:
a) injecting a sample into the sample channel,
b) impressing a voltage on the anode-cathode pair,
c) detecting at least one analyte, for example via an immunoassay technique, in at least one part of the sample channel and/or in a fractionation channel and/or in a gel pad and/or in a detection chamber and/or in an analyte detector, and/or
   collecting at least one analyte from the sample channel, in particular via the sample outlet, and/or at least one fractionation channel, in particular via a fractionation outlet, and/or at least one of the gel pads, in particular via a gel outlet.

Within the scope of a preferred embodiment of the method for fractionating, detecting and/or collecting analytes according to the invention, the method further comprises the steps:
d) transferring the sample from the area between the anode-cathode pair to the area of an additional anode-cathode pair by opening at least one flow barrier and/or operating a pressure means,
e) impressing a voltage on the additional anode-cathode pair,
f) detecting at least one analyte, for example via an immunoassay technique, in at least one part of the sample channel and/or in a fractionation channel and/or in a of the gel pad and/or in a detection chamber and/or in an analyte detector, and/or
   collecting at least one analyte from the sample channel, in particular via the sample outlet, and/or a fractionation channel, in particular via a fractionation outlet, and/or a gel pad.

Another subject of the present invention is a manufacturing method for a biochip according to the present invention, comprising the steps:
a) forming at least one recess in a bottom substrate,
   providing a cover substrate with at least holes, in particular serving in the finished biochip as sample inlet, sample outlet, anode inlet, cathode inlet, gel inlet, gel outlet, fractionation inlet and/or fractionation outlet, at positions that correspond to the position of the sample channel, the gel pads and/or fractionation channels to be formed on the bottom substrate, and
   optionally providing a manufacturing cover substrate having holes corresponding at positions that correspond to the position/s of the gel pad/s to be formed,
b) applying a water repellant agent to the areas on the bottom substrate and/or on the cover substrate and/or on the manufacturing cover substrate, that correspond to the position of the sample channel and/or the fractionation channels and/or flow barriers and/or reservoirs and/or chambers to be formed,
c) covering the bottom substrate with the cover substrate or the manufacturing cover substrate,
d) introducing through each hole that corresponds to the position of a different gel pad to be formed a different gel formulation,
e) polymerizing the gel formulation/s, and
f) optionally exchanging the manufacturing cover substrate to the cover substrate.

This manufacturing method according to the invention advantageously allows it to manufacture a microfluidic biochip according to the invention.

Preferably, the recess in the bottom substrate has essentially the overall outline of the sample channel, the gel pads and/or fractionation channels to be formed. For example, a biochip with a sample channel and two gel pads may be based on a recess with a cross-shaped overall outline (FIG. 1) and a biochip with a sample channel, four gel pads and two fractionation channels may be based on a recess with an overall outline in form of a cross with three crossbars (FIG. 2). The bottom substrate, the cover substrate and/or the manufacturing cover substrate can for example be a glass substrate or a plastic substrate, for example polypropylene (PP), polycarbonate (PC), polymethylmethacrylate (PMMA). The recess in a bottom substrate can for example be formed via glass etching or photolithography, for example by using a photoresist such as SUB, or injection molding. For binding the silane group of water repellant agents and/or gel binding agent, the method further comprises the step a1): providing the plastic substrate, in particular the injection molded plastic substrate, with a SiOx layer. This thin layer can for example be applied by evaporation and/or sputter techniques.

The water repellant agent advantageously act as hydrophobic stop for controlling the formation of the sample channel, the fractionation channels, reservoirs and/or chambers during gel formulation (see FIGS. 5a to 5c and figure description).

Suitable water repellant agents according to the present invention are for example 1H,1H,2H,2H-perfluoroalkyltrihalogenosilanes, such as 1H,1H,2H,2H-perfluorohexyltrichlorosilane, 1H,1H,2H,2H-perfluorooctyltrichlorosilane, 1H,1H,2H,2H-perfluorodecyltrichlorosilane, and/or 1H,1H,2H,2H-perfluorododecyltrichlorosilane, in particular 1H,1H,2H,2H-perfluorodecyltrichlorosilane, and/or 1H,1H,2H,2H-perfluoroalkyltrialkoxysilanes, for example 1H,1H,2H,2H-perfluorohexyltrimethoxysilane, 1H,1H,2H,2H-perfluorooctyltrimethoxysilane, 1H,1H,2H,2H-perfluorodecyltrimethoxysilane, 1H,1H,2H,2H-perfluorododecyltrimethoxysilane, 1H,1H,2H,2H-perfluorohexyltriethoxysilane, 1H,1H,2H,2H-perfluorooctyltriethoxysilane, 1H,1H,2H,2H-perfluorodecyltriethoxysilane and/or 1H,1H,2H,2H-perfluorododecyltriethoxysilane, in particular 1H,1H,2H,2H-perfluorodecyltrimethoxysilane and/or 1H,1H,2H,2H-perfluorodecyltriethoxysilane, and/or Teflon (poly-perfluoroethylene) based compounds, for example Teflon AF1600, and/or compounds of the formula (III):

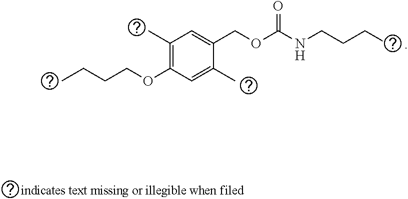

The use of a manufacturing cover substrate and the subsequent exchange to the cover substrate has the advantage that the water repellant agent areas, that are applied for the formation of the sample channel, the fractionation channels, reservoirs and/or chambers, must not be coated on the cover substrate and thereby do not effect the sample, water or buffer in these finished biochip.

However, it is also possible only to use a cover substrate. After polymerization of the gel formulations, the water repellant agent can thereby, for example at the position of the sample channel and/or the fractionation channels and/or reservoirs and/or chambers, be converted into a hydrophilic compound, in particular by applying a radiation, and/or removed by washing, for example the sample channel and/or the fractionation channel and/or reservoir and/or chamber, with a solvent. For example, Teflon AF can be removed by flushing the sample channel and/or the fractionation channel and/or reservoir and/or chamber with a perfluoroalkane, such as perfluorohexane.

Within the scope of a preferred embodiment of the manufacturing method according to the invention, the method further comprises the step b1) applying a gel binding agent to the areas of the bottom and/or cover substrate that correspond to the position of the gel pads to be formed.

By this means the walls or wall parts, where the gel pads shall be formed are functionalized for chemical binding with the gel and undesired leakage of liquids is prevented. Suitable gel binding agents for glass substrates and plastic substrates provided with a layer of SiOx are for example methacryloxyalkyltrialkoxysilanes, such as methacryloxymethyltrimethoxysilane, methacryloxyethyltrimethoxysilane, methacryloxypropyltrimethoxysilane, methacryloxymethyltriethoxysilane, methacryloxyethyltriethoxysilane, methacryloxypropyltriethoxysilane, in particular methacryloxypropyltrimethoxysilane. Suitable gel binding agents for plastic, in particular acrylate or acrylamide, substrates without SiOx layer are for example aminofunctionalized silanes, in particular primary aminofunctionalized silanes, such as aminoalkyltrialkoxysilanes, in particular aminopropyltrimethoxysilane and/or aminopropyltriethoxysilane. Advantageously these compounds can form covalent bonds with acrylates or acrylamides via the Michaels addition.

Within the scope of another preferred embodiment of the manufacturing method according to the invention, the gel formulation comprises acrylamide monomers:

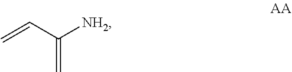

N,N′-methylenebisacrylamide monomers:

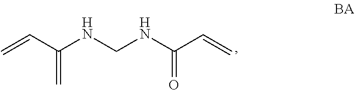

and

monomers comprising one or more pH-buffering subunits (immobiline monomers), for example acrylamide monomers comprising one or more pH-buffering subunits, such as immobiline A (buffering the gel at 26 pH 4.5) of the formula I:

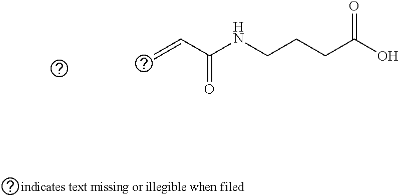

and

immobiline B (buffering the gel at ≈pH 8.5) of the formula II:

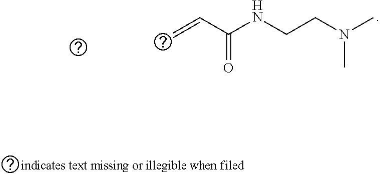

The gel formulation is generally made by mixing ≧0.01% by weight to ≦20% by weight, in particular ≧2% by weight to ≦10% by weight, of monomers in deionized water. The ratio acrylamide to bisacrylamide is for example in a range of ≧20:1 to ≦100:1, for example about 40:1. To obtain a good buffering capacity at pH of the used immobiline monomers, the concentration of the immobiline monomers can for example be in a range of ≧1 mM to ≦50 mM, for example about 25 mM.

Another subject of the present invention is the use of a biochip according to the invention
for rapid and sensitive detection of proteins, metabolites, glycoproteins and/or peptides in complex biological mixtures, such as blood, saliva, urine,
for on-site (point-of-need) testing or for diagnostics in centralized laboratories or in scientific research,
in a biosensor, in particular microfluidic biosensor, used for molecular diagnostics,
for high throughput screening in chemistry, pharmaceuticals or molecular biology, and/or
for protein diagnostic for cardiology, infectious diseases, oncology, food, environment and/or metabolomics.

### BRIEF DESCRIPTION OF THE DRAWINGS

Additional details, features, characteristics and advantages of the object of the invention are disclosed in the subclaims, the figures and the following description of the respective figures and examples, which—in an exemplary fashion—show several preferred embodiments of a biochip according to the invention.

FIG. 1 shows a schematic top view of a biochip according to a first embodiment of the present invention.

FIG. 2 shows a schematic top view of a biochip according to a second embodiment of the present invention with multiple fractionation chambers.

FIG. 3 shows a schematic top view of a biochip according to a third embodiment of the present invention with an additional anode-cathode pair and flow barriers separating the sample channel.

FIG. 4 shows a schematic perspective view of the biochip according to the first embodiment of the present invention.

FIGS. 5a to 5c show schematic cross-sectional views of hydrophobic stops according to the present invention.

FIG. 6 shows a schematic top view of a biochip according to a forth embodiment of the present invention with flow barriers separating the sample channel, two gel pads and two fractionation channels from detection related reservoirs and chambers.

FIGS. 7a and 7b show the separation of phycocyanin having an isoelectric point of 4.6 from a standard protein mix by a biochip according to the first embodiment of the present invention.

### DETAILED DESCRIPTION OF EMBODIMENTS

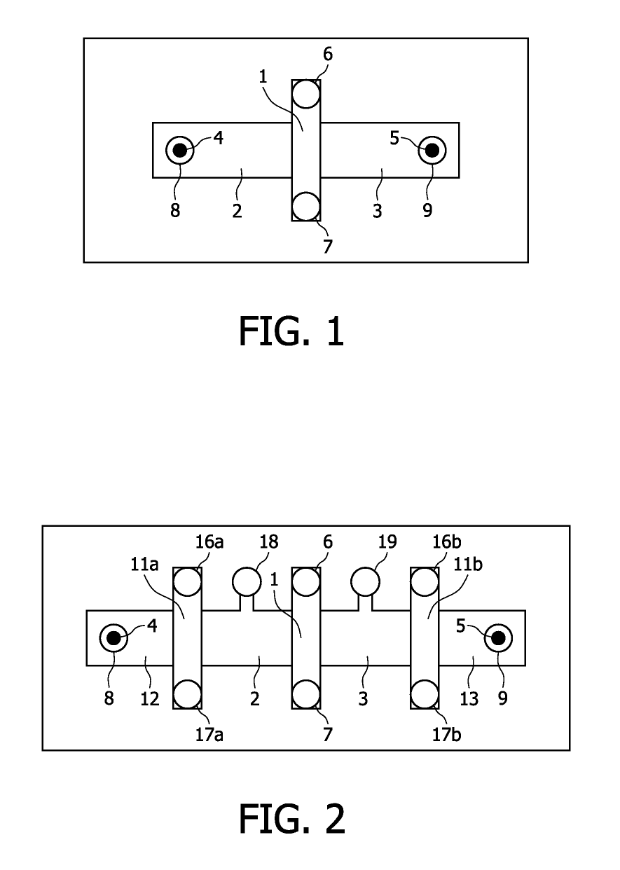

FIG. 1 shows a biochip according to the present invention in its simplest form. The biochip comprises a sample channel 1, a first gel pad 2 having a first pH value (pH1), a second gel pad 3 having a second pH value (pH2) different to the first pH value (pH1), and an anode-cathode pair 4, 5. The first gel pad 2 thereby forms at least one part of a sample channel wall and the second gel pad 3 forms at least one part of another sample channel wall opposite to the sample channel wall part formed by the first gel pad. By other words, the sample channel is sandwiched between the gel pad 2 having the first pH value (pH1) and the gel pad 3 having the second pH value (pH2). The first 2 and the second 3 gel pad therefore form according to the invention at least two opposite wall parts of the sample channel 1.

The pH values of the gel pads 2, 3 thereby increase from the gel pad closest to the anode 4 to the gel pad closest to the cathode 5. The pH value (pH1) of the first gel pad 2 is therefore lower than the pH value (pH2) of the second gel pad 3.

For ensuring the isoelectric movement, at least one part of the first gel pad 2, at least one part of the second gel pad 3 and the part of the sample channel 1, whose opposite wall parts are formed by the first 2 and the second 3 gel pad, are arranged between the anode 4 and the cathode 5 of the anode-cathode pair 4, 5 as shown in FIG. 1.

According to the invention, the two external gel pads 2, 3 of the anode-cathode pair 4, 5 are preferably electrically connected to the anode 4 and cathode 5, respectively. In the embodiment shown in FIG. 1, therefore the anode 3 is electrically connected to the first gel pad 2 and the cathode 4 is electrically connected to the second gel pad 3.

By such an arrangement the biochip advantageously removes all the analytes from the sample in the sample channel except the analytes having with an isoelectric point (pI) between the first (pH1) and the second (pH2) value.

FIG. 1 shows that the sample channel 1 is provided with a sample inlet 6 and a sample outlet 7 to introduce the sample containing the analytes, such as proteins, metabolites, glycoproteins and/or peptides and to remove the fractionated analytes after the isoelectric focusing, e.g. by using a pipette or a pressure means. For the same reason, also the fractionation channels 11a, 11b shown in FIG. 2 can be provided with a fractionation inlet 16a, 16b and outlet 17a, 17b. During the isoelectric focusing preferably the sample inlet 6 and outlet 7 and optionally the fractionation inlets 16a, 16b and outlets 17a, 17b shown in FIG. 2, are preferably closed.

As shown in FIG. 1, the two external gel pads 2, 3 of one anode-cathode pair 4, 5 are provided with an anode inlet 8 and a cathode inlet 9, respectively. By this means, advantageously not only an electric contact of the cathodes and the gels, but also the manufacture of the biochip according to the invention can be simplified. The gel pads 2, 3 can for example be electrically connected to the electrodes by inserting the anode 4 through the anode inlet 8 and inserting the cathode through the cathode inlet 9. To overcome detrimental side effects caused by the electrodes gas formed during electrophoresis, such as gas bubbles inside the gel pads 2, 3, the anode 4 and cathode 5 preferably do not directly contact the gel pads 2, 3 according to the invention. To ensure the electrical contact of the electrodes 4, 5 and the gel pads 2, 3 thereby a liquid, in particular an aqueous liquid, such as water or a buffer solution, is used. This liquid can easily be added through the anode 8 and cathode inlet 9.

FIG. 2 shows a schematic top view of a biochip according to a second embodiment of the present invention with multiple fractionation channels 11a, 11b. In the embodiment shown in FIG. 1, the biochip comprises two fractionation channels 11a, 11b. The fractionation channels 11a, 11b are preferably filled with an aqueous liquid, such as water or a buffer solution.

FIG. 2 shows that the biochip comprises for each fractionation channel 11a, 11b an additional gel pad 12, 13. Thereby each additional gel pad 12, 13 has a pH value different to the pH values of the other gel pads 2, 3, 12, 13. FIG. 2 shows that the first additional gel pad 12 and the first gel pad 2 form two opposite wall parts of the first fractionation channel 11a and the second additional gel pad 13 and the second gel pad 3 form opposite wall parts of the second fractionation channel 11b.

For ensuring the isoelectric movement, at least one part of the additional gel pad 12, 13 and the part of the fractionation channel 11a, 11b, whose opposite wall parts are formed by the additional gel pad 12, 13 and the first gel pad 2 or the second gel pad 3 or a further additional gel pad, are arranged between the anode 3 and the cathode 4 of the anode-cathode pair 4, 5. To simplify the manufacture and to enable the connection with other means, each the internal gel pad 2, 3 of the anode-cathode pair 4, 5 is preferably provided with a gel inlet 18, 19.

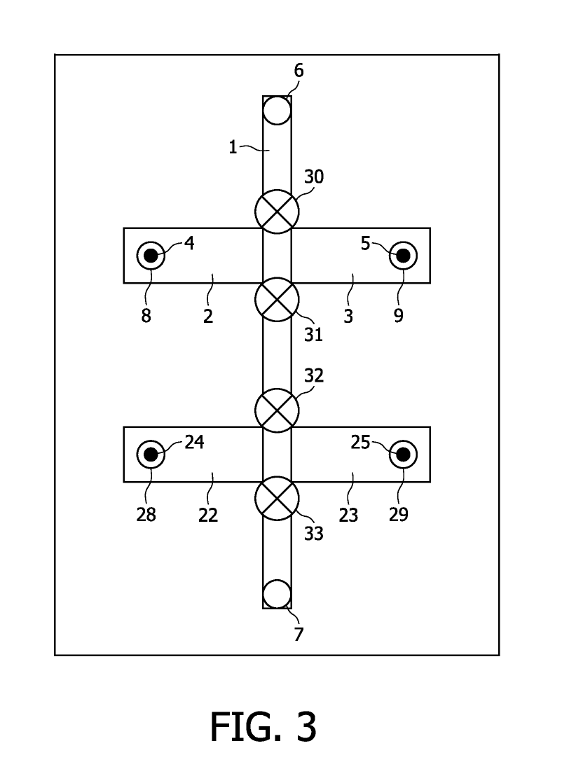

FIG. 3 shows a schematic top view of a biochip according to a third embodiment of the present invention with an additional anode-cathode pair 24, 25 and flow barriers 30, 31, 32, 33 separating the sample channel 1. According to the invention, the biochip comprises for each additional anode-cathode pair 24, 25 at least two further gel pads 22, 23 having pH values different to each other and to the pH values of the other gel pads 2, 3, 12, 13. Analogously to the first embodiment, the two gel pads 22, 23 form at least two opposite wall parts of the sample channel 1. To ensure the isoelectric movement, at least one part of each of the two gel pads 22, 23 and the part of the sample channel 1, whose opposite wall parts are formed by the two gel pads 22, 23, are arranged between the anode 24 and the cathode 25 of the additional anode-cathode pair 24, 25.

In the embodiment shown in FIG. 3, the biochip comprises four flow barriers 30, 31, 32, 33 for separating the interaction of the sample with the gel pads 2, 3, 12, 13 of the first anode-cathode pair 4, 5 and with the gel pads 22, 23 of the additional anode-cathode pairs 24, 25. For example, these flow barriers 30, 31, 32, 33 may be hydrophobic stop barriers. As shown in FIG. 3 each anode-cathode pair 4, 5, 24, 25 comprises a first 30, 32 and a second 31, 33 flow barrier. These flow barriers are positioned at the beginning and at the end of the parts of the sample channel 1, whose opposite wall parts are formed by the two gel pads 2, 3, 22, 23 of the anode-cathode pairs 4, 5, 24, 25. By this means, the sample is advantageously kept in the area between the anode and the cathode of the anode-cathode pair during isoelectric focusing.

Advantageously, an embodiment according to FIG. 3 makes it possible to firstly remove for example high-abundant proteins (HAP) at the first anode-cathode pair 4, 5 and subsequently applying a further fractionation in the pI range of interest at the additional anode-cathode pair 24, 25.

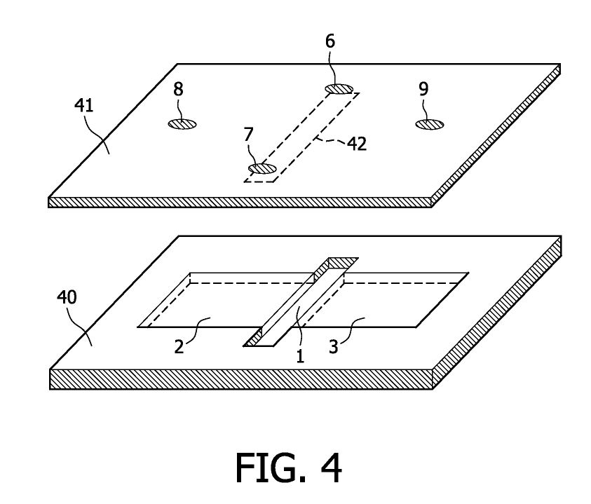

FIG. 4 shows a schematic perspective view of the biochip according to the first embodiment of the present invention, shown in FIG. 1. FIG. 4 illustrates that a biochip according to the invention can comprise a bottom 40 and a cover 41 substrate.

As shown in FIG. 4, the bottom substrate 40 comprises a recess having cross shaped overall outline of the sample channel 1 and the gel pads 2, 3. The bottom substrate 40 may be a glass substrate. The recess is thereby preferably formed via glass etching or photolithography or injection molding followed by SiOx coating.

FIG. 4 shows that the cover substrate 41 is provided with holes 6, 7, 8, 9 at positions that correspond to the position of the sample channel 1 and the gel pads 2, 3 to be formed on the bottom substrate 40. These holes 6, 7, 8, 9 in particular serve in the finished biochip as sample inlet 6, sample outlet 7, anode inlet 8 and cathode inlet 9.

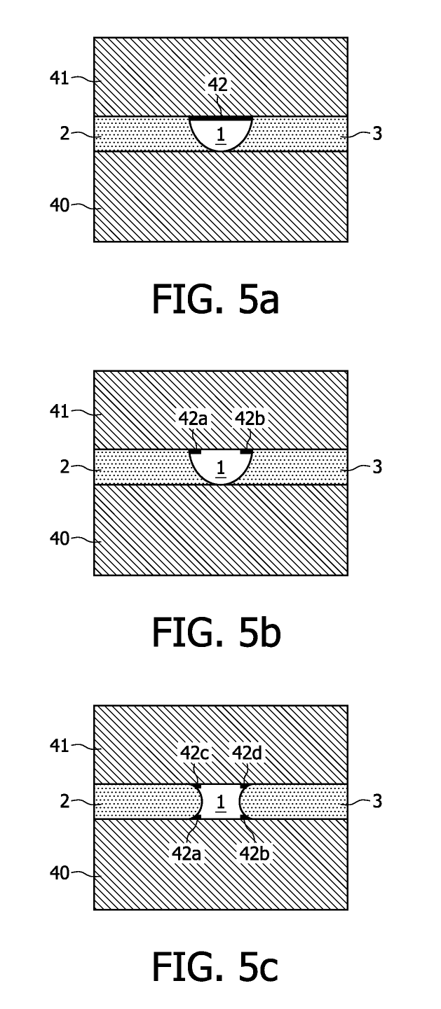

Furthermore FIG. 4 shows, that the cover substrate 41 comprises on the side facing the bottom substrate 40 a water repellant coating 42. This water repellant coating 42 induces the effects described within the context of FIGS. 5a to 5c and thereby enables the formation of the sample channel 1.

Covering the bottom substrate 40 with the cover substrate 41, filling one gel formulation through hole 8 and another gel formulation through hole 9, polymerizing the gel formulations, introducing the anode 4 through hole 8 and introducing the cathode 5 through hole 9, is the simplest method for manufacturing a biochip according to the invention.

However, a biochip according to the invention can be manufactured by many other ways.

For example, the bottom substrate 40 can firstly be covered with a manufacturing cover substrate having holes 8, 9 corresponding to the positions in which the gel pads 2, 3 shall be formed and a water repellant coating 42 on the area corresponding to the area in which the sample channel 1 shall be formed. Such a manufacturing cover substrate makes it possible to manufacture the gel pads 2, 3 and the sample channel 1. After polymerization of the gel formulations, the manufacturing cover substrate can be exchanged to a cover substrate 42 having no water repellant coating.

FIGS. 5a to 5c show schematic cross-sectional views of hydrophobic stops according to the present invention. As illustrated by FIGS. 5a to 5c, a liquid, such as a gel formulation or the sample, can be stopped by applying a linear 42a-42d or two-dimensional 42 water repellant coating to one or several inner sides of a capillary, such as the sample channel. By this effect, not only the sample channel 1, fractionation channels 11a, 11b, reservoirs 51a, 51b, 52a, 52b and chambers 53a-53e, 53a-54e, but also hydrophobic stop barriers 50a-50o can be manufactured.

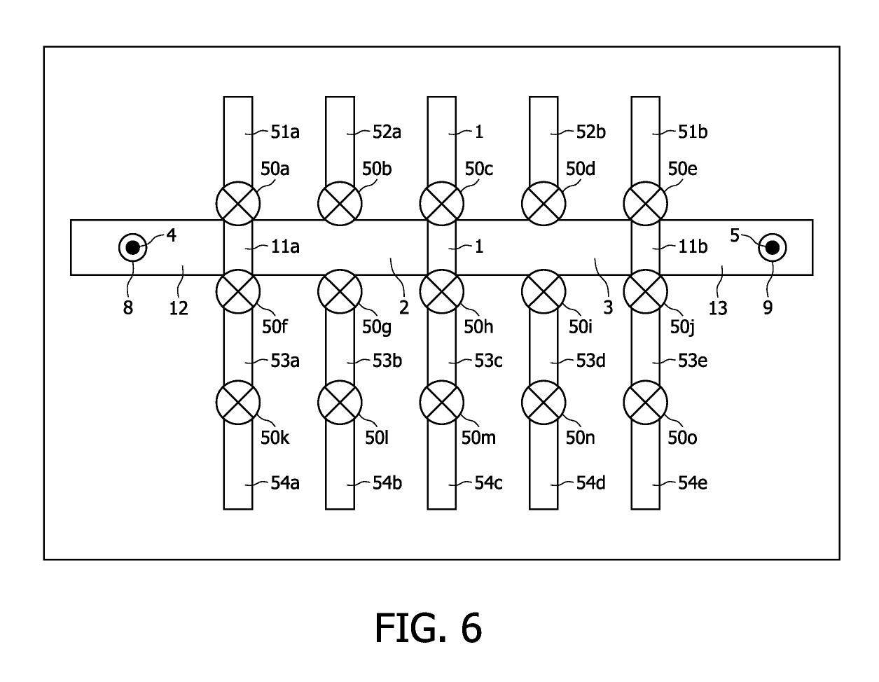

FIG. 6 shows a schematic top view of a biochip according to a forth embodiment of the present invention with flow barriers 50a-50o separating the sample channel 1, two gel pads 2, 3 and two fractionation channels 11a, 11b from detection related reservoirs 51a, 51b, 52a, 52b and chambers 53a-53e, 54a-54e. FIG. 6 illustrates that the sample channel 1, the two gel pads 2, 3 and the two fractionation channels 11a, 11b are each provided with a first 50a-50e and a second 50f-50j flow barrier, arranged on opposite sides of the sample channel 1, the gel pads 2, 3 and the fractionation channels 11a, 11b, respectively. By opening the first flow barriers 50a-50e the sample channel 1, the two gel pads 2, 3 and the two fractionation channels 11a, 11b are connectable to buffer reservoirs and/or a pressure means. By opening the second flow barriers 50f-50j the sample channel 1, the two gel pads 2, 3 and the two fractionation channels 11a, 11b are connectable to an analyte detector and/or analyte collector and/or a further analyte separator. In FIG. 6, the sample channel 1, the two gel pads 2, 3 and the two fractionation channels 11a, 11b are in particular connectable by opening the second flow barriers 50f-50j to a detection chamber 53a-53e. In the embodiment shown in FIG. 1, the detection chambers 53a-53e comprises at least one capture probe and are connectable by opening a third flow barrier 50k-50l to a detection probe reservoir 54a-54e comprising at least one detection probe.

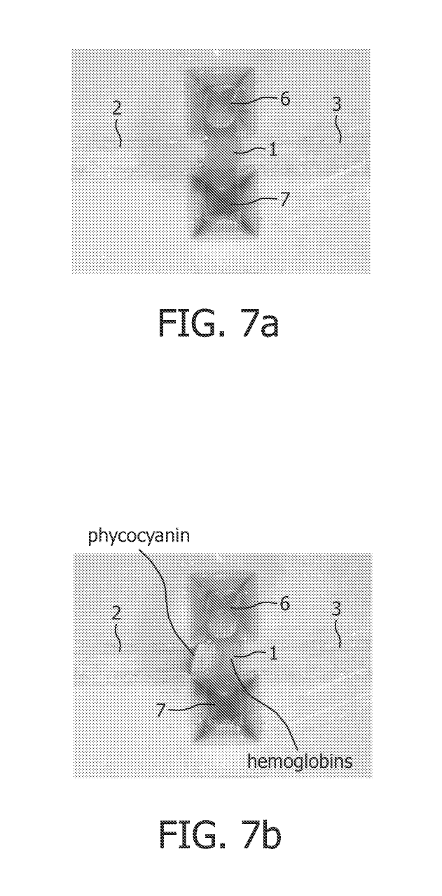

FIGS. 7a and 7b show the separation of phycocyanin having an isoelectric point of 4.6 from a standard protein mix by a biochip according to the first embodiment of the present invention.

For this example, the biochip according to the first embodiment of the present invention was made according to the following procedure:

1. Providing a bottom substrate by:
cleaning a glass substrate with soap (Extran 02 (Merck), rinsing and blow-drying the bottom substrate,
exposing the glass substrate for 10 minutes to UV-ozone and UVP-100,
masking the whole substrate area except the position of the sample channel to be formed with scotch tape (sample channel width about 1 mm),
exposing the substrate for 1 hour at a pressure of 1 mbar to perfluorodecyltrichlorosilane (purchased from ABCR),
removing the scotch tape,
forming a cross-shaped recess on the substrate with double-sided tape (height about 100 μm),

2. Providing a cover substrate by:
cleaning a glass substrate with soap (Extran 02 (Merck), rinsing and blow-drying the bottom substrate,
exposing the glass substrate for 10 minutes to UV-ozone and UVP-100,
forming in- and outlet holes 6, 7, 8, 9 to the substrate,

3. Assembling the cover substrate and the bottom substrate,

4. Preparing the gel formulations by:
mixing 7% by weight of acrylamide/bis-acrylamide (ratio 37.5:1) dissolved in de-ionized water with 1% by weight of the photoinitiator Irgacure 2959,
mixing one part of this composition with 25 mM Immobiline pH 6.6 (Fluka) and the other part of this composition with 25 mM Immobiline pH 7.4 (Fluka),

5. Filling the gel formulations into the holes 8 and 9, respectively by using Eppendorf 1-10 μl syringe, and

6. Exposing the arrangement to ultra violet light (Philips PL10, 3 mWcm⁻²) in a nitrogen chamber for 20 minutes.
For isoelectric fractionation of the isoelctric focusing (IEF) standard protein mix from BioRad, catalogue no 161-0310:
the anode 4 was connected to first gel pad 2 having a pH value of 6.6 via water droplet, and
the cathode 5 was connected to the second gel pad 3 having a pH value of 7.4 via water droplet, and
a voltage of at most 300 V and a current of at most 20 μA were applied for 10 minutes.

FIG. 7a clearly shows that phycocyanin having an isoelectric point of 4.6 is transferred within 10 minutes to the first gel pad 2. The separation of phycocyanin from the IEF standard protein mix (BioRad, catalogue no 161-0310) can therefore rapidly be achieved by a biochip according to the present invention.

1. An isoelectric focusing biochip comprising
a microfluidic sample channel (1),
a first gel pad (2) having a first pH value (pH1),
a second gel pad (3) having a second pH value (pH2) different to the first pH value (pH1), and
an anode-cathode pair (4, 5),
whereas the first (2) and the second (3) gel pad form at least two opposite wall parts of the sample channel (1), and
whereas at least one part of the first gel pad (2), at least one part of the second gel pad (3) and the part of the sample channel (1), whose opposite wall parts are formed by the first (2) and the second (3) gel pad, are arranged between the anode (4) and the cathode (5) of the anode-cathode pair (4, 5).

2. Biochip according to claim 1, characterized in that the biochip comprises at least one microfluidic fractionation channel (11a, 11b),
whereas the biochip comprises for each fractionation channel (11a, 11b) an additional gel pad (12, 13) having a pH value different to the pH values of the other gel pads (2, 3, 12, 13)
whereas the additional gel pad (12, 13) and the first gel pad (2) or the second gel pad (3) or a further additional gel pad form at least two opposite wall parts of the fractionation channel (11a, 11b), and
whereas at least one part of the additional gel pad (12, 13) and the part of the fractionation channel (11a, 11b), whose opposite wall parts are formed by the additional gel pad (12, 13) and the first gel pad (2) or the second gel pad (3) or a further additional gel pad, are arranged between the anode (3) and the cathode (4) of the anode-cathode pair (4, 5).

3. Biochip according to claim 1, characterized in that the biochip comprises at least one additional anode-cathode pair (24, 25),
whereas the biochip comprises for each additional anode-cathode pair (24, 25) at least two further gel pads (22, 23) having pH values different to each other and to the pH values of the other gel pads (2, 3, 12, 13),
whereas the two gel pads (22, 23) form at least two opposite wall parts of the sample channel (1), and
whereas at least one part of each of the two gel pads (22, 23) and the part of the sample channel (1), whose opposite wall parts are formed by the two gel pads (22, 23), are arranged between the anode (24) and the cathode (25) of the additional anode-cathode pair (24, 25).

4. Biochip according to claim 1, characterized in that
the sample channel (1) is provided with a sample inlet (6) and a sample outlet (7); and
the two external gel pads (2, 3; 12, 13) of one anode-cathode pair (4, 5; 24, 25) are provided with an anode inlet (8) and a cathode inlet (9); and
each fractionation channel (11a, 11b) is provided with a fractionation inlet (16a, 16b) and a fractionation outlet (17a, 17b).

5. Biochip according to claim 1, characterized in that the sample channel (1) is provided with at least one flow barrier (31, 32) for separating the interaction of the sample with the gel pad/s (2, 3, 12, 13) of the anode-cathode pair (4, 5) and with the gel pad/s (22, 23) of the additional anode-cathode pairs (24, 25).

6. Biochip according to claim 1, characterized in that at least one fractionation channel (11a, 11b) is connected or connectable via a fractionation outlet (17a, 17b) to an analyte detector and/or analyte collector and/or a further analyte separator.

7. Biochip according to claim 1, characterized in that the sample channel (1) is connected or connectable via the sample outlet (7) to an analyte detector and/or analyte collector and/or a further analyte separator.

8. Method for fractionating, detecting and/or collecting analytes comprising the steps:
a) injecting a sample into the sample channel (1),
b) impressing a voltage on the anode-cathode pair (3,4),
c) detecting at least one analyte in at least one part of the sample channel (1) and/or in a fractionation channel (11a, 11b) and/or in a gel pad (2, 3, 12, 13, 22, 23) and/or in an analyte detector, and/or collecting at least one analyte from the sample channel (1) and/or a fractionation channel (11a, 11b) and/or a the gel pad (2, 3, 12, 13, 22, 23).

9. Method according to claim 8, characterized in that the method further comprises the steps:
d) transferring the sample from the area between the anode-cathode pair (4, 5) to the area of an additional anode-cathode pair (24, 25) by operating at least one flow barrier (30, 31, 32, 33) and/or pressure means,
e) impressing a voltage on the additional anode-cathode pair (24, 25),
f) detecting at least one analyte in at least one part of the sample channel (1) and/or in a fractionation channel (11a, 11b) and/or in a the gel pad (2, 3, 12, 13, 22, 23) and/or in an analyte detector, and/or
collecting at least one analyte from the sample channel (1) and/or a fractionation channel (11a, 11b) and/or a gel pad (2, 3, 12, 13, 22, 23).

10. Manufacturing method for a biochip according to claim 8, comprising the steps:
a) forming at least one recess in a bottom substrate (40),
providing a cover substrate (41) with at least holes (6, 7, 16a, 16b, 17a, 17b, 8, 9, 18, 19) at positions that correspond to the position of the sample channel (1), the gel pads (2, 3, 12, 13, 22, 23) and/or fractionation channels (11a, 11b) to be formed on the bottom substrate (40), optionally providing a manufacturing cover substrate having holes at positions that correspond to the position/s of the gel pad/s (2, 3, 12, 13, 22, 23) to be formed,
b) applying a water repellant agent to the areas (42) on the bottom substrate (40) and/or on the cover substrate (41) and/or on the manufacturing cover substrate, that correspond to the position of the sample channel (1) and/or the fractionation channels (11a, 11b) and/or flow barriers (30-33; 50a-50o) and/or reservoirs (51a, 51b, 52a, 52b) and/or chambers (54a-54e) to be formed,
c) covering the bottom substrate (40) with the cover substrate (41) or the manufacturing cover substrate,
d) introducing through each hole that corresponds to the position of a different gel pad (2, 3, 12, 13, 22, 23) to be formed a different gel formulation,
e) polymerizing the gel formulation/s, and
f) optionally exchanging the manufacturing cover substrate to the cover substrate (41).

11. Manufacturing method according to claim 10, characterized in that the bottom substrate (40), the cover substrate (41) and/or the manufacturing cover substrate is a glass substrate or a plastic substrate.

12. Manufacturing method according to claim 10, characterized in that the recess in the bottom substrate is formed via glass etching or photolithography or injection molding.

13. Manufacturing method according to claim 10, characterized in that the method further comprises the step a1): providing the plastic substrate with a SiOx layer.

14. Manufacturing method according to claim 10, characterized in that the method further comprises the step b1) applying a gel binding agent to the areas of the bottom substrate (40) and/or cover substrate (41) that correspond to the position of the gel pads (2, 3, 12, 13, 22, 23) to be formed.

15. Use of a biochip according to claim 1
for rapid and sensitive detection of proteins, metabolites, glycoproteins and/or peptides in complex biological mixtures,
for on-site (point-of-need) testing or for diagnostics in centralized laboratories or in scientific research,
in a biosensor used for molecular diagnostics,
for high throughput screening in chemistry, pharmaceuticals or molecular biology, and/or
for protein diagnostic for cardiology, infectious diseases, oncology, food, environment and/or metabolomics.
